(19) United States
(12) Patent Application Publication
(10) Pub. No.: US 2006/0291383 A1
(43) Pub. Date: Dec. 28, 2006

(54) Methods for quality of service reverse link admission and overload control in a wireless system

(76) Inventors: Qi Bi, Morris Plains, NJ (US); Stanley Vitebsky, Morristown, NJ (US); Yang Yang, Parsippany, NJ (US); Jialin Zou, Randolph, NJ (US)

Correspondence Address: HARNESS, DICKEY & PIERCE, P.L.C., P.O. BOX 8910, RESTON, VA, 20195, US

(21) Appl. No.: 11/158,359

(22) Filed: Jun. 22, 2005

(51) Int. Cl. H04L 12/26; H04L 1/00; G01R 31/08; H04Q 7/00

(52) U.S. Cl. 370/229; 370/328

(57) ABSTRACT

At least one traffic flow belonging to one of a plurality of service classes may be admitted based on at least one admission condition and overload state associated with the service class to which the at least one traffic flow belongs.

### BACKGROUND OF THE INVENTION

Reverse or uplink communication (e.g., from mobile station to base station) is a major concern in various wireless communication standards (e.g., cdma2000, UMTS, etc.) supporting application level end-to-end quality of service (QoS). Wireless users in a next generation wireless system may establish a connection with one or more base stations (hereinafter referred to as a system). This connection may be referred to as a call connection, and may include multiple traffic flows. Each individual traffic flow may be associated with a different application, for example, voice, data, video, etc.

Within each call connection, different traffic flows may be classified, and subsequently, treated differently based on respective QoS requirements defmed for each individual traffic flow. More specifically, for example, in next generation wireless CDMA High Rate Packet Data Systems, resource management and/or traffic handling of traffic flows may be handled differently via differentiated services (DiffServ) model defined by the Internet Engineering Task Force (IETF).

In this example, the DiffServ provides a way to configure and handle traffic flows with different transport priorities, or in other words, different quality of service requirements. For example, transport priorities (e.g., QoS classes or traffic profiles) may be classified into three categories: expedited forwarding (EF), assured forwarding (AF), and best effort (BE). In operation, EF may be used to provide a lower latency, lower jitter, assured bandwidth service such as required by, for example, real-time packet voice (e.g., VoIP) or video traffic flows. AF may be used to support services (e.g., traffic flows) requiring certain minimum throughput, but that may not have strict latency requirements. BE may not provide quality of service guarantees with respect to latency and/or throughput, but instead may utilize system resources opportunistically.

QoS enabled systems may follow certain principles in managing resources. In order to support simple high speed data services, , conventional systems (e.g. the basic DOrA (Data Optimized Revision A) or DOr0 (Data Optimized Revision 0) systems) may employ reverse link overload control (ROC) on a per-call connection or per-user basis. Historically, the conventional ROC works based on the Rise-Over-Thermal (RoT). For example, the RoT is compared to a target threshold to trigger the loading control. If the RoT exceeds the threshold, an overload is determined and actions will be taken to reduce the system load.

If normal ROC operation is still not able to overcome RF overload, regular congestion overload control (COC) will take action including preventing admission of new call connections (or users) or muting some low priority active call connections (or users).

However, the above conventional methods only allow for overload control on a per-call or per-user basis and, thus, certain higher level traffic flows (within a call) may be unnecessarily blocked when overload control is performed. As a result, by simply using the conventional method, QoS requirements of many service classes may not be ensured.

### SUMMARY OF THE INVENTION

An example embodiment of the present invention may determine whether to admit at least one traffic flow belonging to one of a plurality of service classes based on at least one admission condition associated with the service class to which the traffic flow belongs and an overload state associated with the service class to which the traffic flow belongs.

Another example embodiment of the present invention may independently determine whether to admit each traffic flow among a plurality of traffic flows belonging to different service classes based on at least one admission condition for a service class to which each traffic flow belongs and an overload state for a service class to which each traffic flow belongs.

Another example embodiment of the present invention may determine whether a traffic flow service class from a plurality of traffic flow service classes is in an overload state based on a congestion overload metric and a first threshold associated with the traffic flow service class.

In example embodiments of the present invention, the traffic flow may be admitted if the overload state indicates that the service class to which the traffic flow belongs is not overloaded and the admission condition is satisfied.

In example embodiments of the present invention, a first admission condition may be satisfied if a current system loading estimate passes a current admission threshold associated with the service class to which the traffic flow belongs.

In example embodiments of the present invention, a second admission condition may be satisfied if a projected system loading estimate associated with the service class to which the traffic flow belongs passes a projected admission threshold associated with the service class to which the traffic flow belongs.

In example embodiments of the present invention, the admission condition may be satisfied if a projected system loading estimate associated with the service class to which the traffic flow belongs passes a projected admission threshold associated with the service class to which the traffic flow belongs.

In example embodiments of the present invention, the current system loading estimate and the current admission threshold associated with the service class to which the traffic flow belongs may be calculated based on an average rise over thermal and fractional average energy to noise ratio of the existing traffic.

In example embodiments of the present invention, the projected system loading estimate and the projected admission threshold associated with the service class to which the traffic flow belongs may be determined based on the existing loading and an energy to noise ratio of the traffic flow.

In example embodiments of the present invention, overload control may be performed for the service class if the overload state indicates an overload. An overload state may indicate an overload if a congestion overload metric is greater than a first threshold associated with the service class.

In example embodiments of the present invention, new traffic flows of the service class to which the traffic flow belongs may be blocked if the congestion overload metric is greater than the first threshold.

In example embodiments of the present invention, at least a portion of existing traffic flows belonging to the service class to which the traffic flow belongs may be muted if the congestion overload metric is greater than a second threshold associated with the service class to which the traffic flow belongs, the second threshold being greater than the first threshold.

In example embodiments of the present invention, at least a portion of existing traffic flows belonging to the service class to which the traffic flow belongs may be dropped if the congestion overload metric is greater than a second threshold associated with the service class to which the traffic flow belongs, the second threshold being greater than the first threshold.

In example embodiments of the present invention, the service class to which the traffic flow belongs may be one of a best effort, an assured forwarding, and an expedited forwarding service class.

In example embodiments of the present invention, admission may be based on at least one of a current admission condition and a projected admission condition.

In example embodiments of the present invention, overload control may be performed if the determining step determines that the traffic flow service class is in overload state, and the traffic flow service class may be in an overload state if the congestion overload metric is greater than the first threshold associated with the traffic flow service class.

### BRIEF DESCRIPTION OF THE DRAWINGS

The present invention will become more fully understood from the detailed description given herein below and the accompanying drawings, wherein like elements are represented by like reference numerals, which are given by way of illustration only and thus are not limiting of the present invention and wherein:

FIG. 1 illustrates portions of a prior art radio access network;

FIG. 2 is a block diagram illustrating a framework for admission control and overload control, according to an example embodiment of the present invention;

FIG. 3 illustrates two state diagrams showing the transitions of state machines for admission and overload control according to an example embodiment of the present invention;

FIG. 4 illustrates a method for flow admission control and overload control, according to an example embodiment of the present invention; and

FIG. 5 illustrates an example of traffic-to-pilot ratio behavior in reverse link (RL) flow classes.

### DETAILED DESCRIPTION OF THE EMBODIMENTS

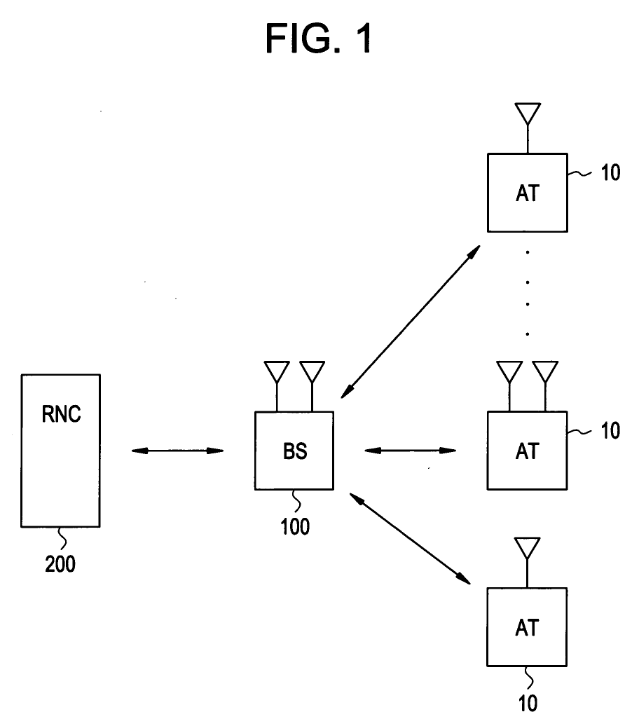

FIG. 1 illustrates a prior art radio access network (RAN). For the purposes of example only, example embodiments of the present invention will be discussed with respect to the RAN of FIG. 1. However, it will be understood from the description of the invention, that the present invention is not limited to this RAN.

As shown, a base station (BS) 100 wirelessly communicates with access terminals (ATs) 10 in a geographical serving area such as a sector or cell served by the BS 100. An AT 10 (also called a mobile station, mobile terminal, mobile, etc.) may be embodied as a wireless phone, a wireless equipped PDA, a wireless equipped computer, etc. The BS 100 communicates with a radio network controller (RNC) 200. As is known, BSs and the RNC associated with those BSs share in the management of call (e.g., voice, data, etc.) processing. Some functions are performed at the BS, while others are performed at the radio network controller. In the RAN presented in FIG. 1, the call management functions for performing reverse link admission and COC are performed at the BS 100. However, it will be understood that these functions could be moved to the RNC 200, or be distributed between the BS 100 and the RNC 200.

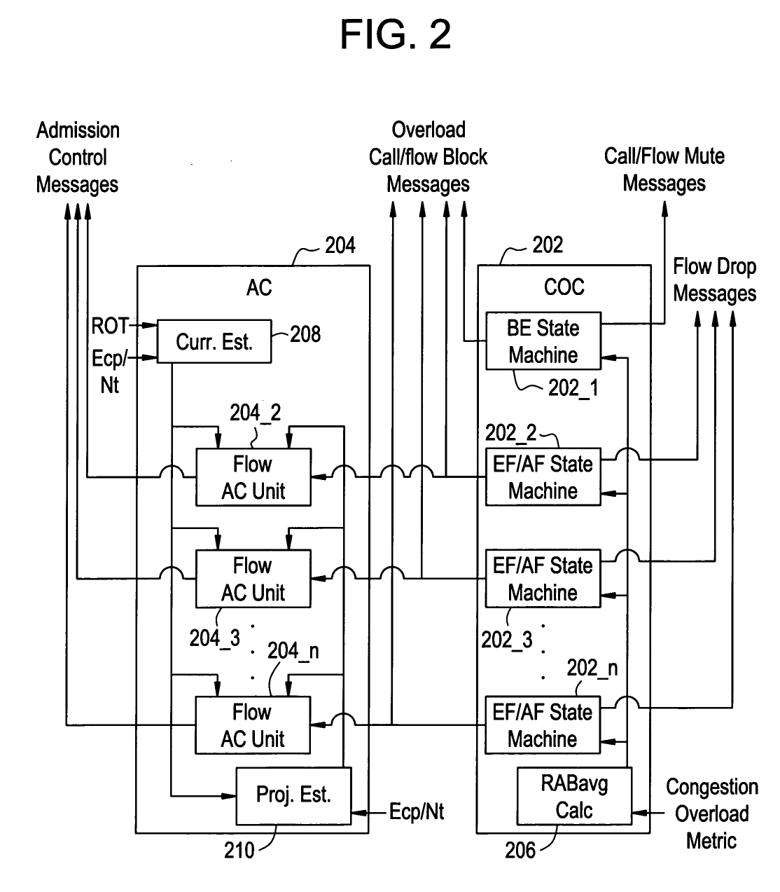

FIG. 2 illustrates a COC unit 202 and an admission control (AC) unit 204, which may be included in the BS 100 of FIG. 1, according to an example embodiment of the present invention. As shown in FIG. 2, the COC unit 202 may further include traffic flow state machines 202_1-202₁₃n and an average RAB (RABavg) calculator 206. The AC unit 204 may further include flow admission control units 204_2-204₁₃n, a current system load estimator 208, and a projected system loading estimator 210.

Referring to FIG. 2, each of the traffic flow state machines 202_1-202_n may determine respective states (e.g., normal, blocking, muting, dropping, etc.) for a respective service class of traffic flows, independent of the states for the other service classes, and may output flow mute messages, flow drop messages, and/or overload flow block messages for controlling muting, dropping, or blocking of traffic flows. Overload flow block messages from state machines 202_2-202_n may also be output to the flow admission control units 204_2-204_n, respectively, and serve as congestion indications, which may indicate a current state (e.g., normal, block, drop, mute, etc.) of the traffic flow state machines 202_2-202_n.

As further shown in FIG. 2, the flow admission control units 204_2-204_n also receive estimations from the current and projected system loading estimators 208 and 210, and generate admission control messages for the second to nth traffic flow service classes. As will be described in detail below, admission control for the lowest (e.g., first) traffic flow class is handled by the state machine 202_1.

Next, the operation of the COC unit 202 will be described in detail followed by a detailed description of the operation of the admission control unit 204.

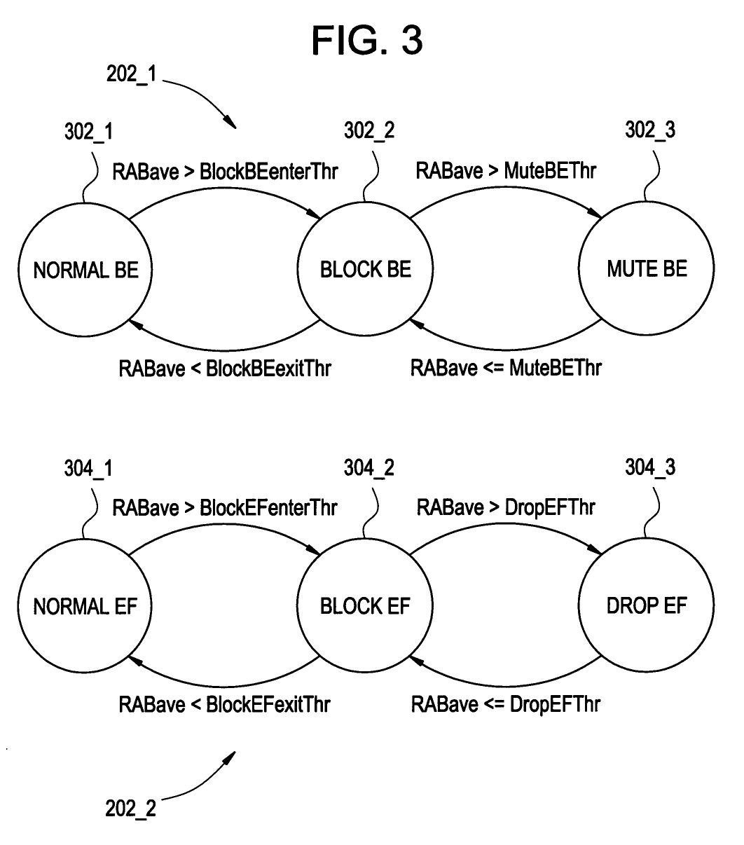

FIG. 3 illustrates transitions between normal, blocking, and muting or dropping states within the state machine 202_1 and 202_2. For exemplary purposes, the state machine 202_1 will be described with respect to a best effort (BE) service class, as a lowest service class, and the state machine 202_2 will be described with respect to an expedited forwarding (EF) service class, as a higher service class. However, it will be understood that state machines associated with other service classes of various priorities may operate in a similar manner.

In example embodiments of the present invention, each state machine 202_1-202_n may have a plurality of different transition thresholds used to determine whether to transition from, for example, a normal state to a blocking state, a blocking state to a muting state, etc.

For example, with regard to the state machine 202_1, in a normal state 302_1, the state machine 202_1 maintains satisfactory control over BE traffic flows by setting (or unsetting) a reverse activity bit (RAB), which controls the transmission rates of the connected users.

The RAB may be set (or unset) by a serving BS in the reverse activity (RA) channel, for example, defined in the 1xEV-DO standard. Within the RA channel, a serving BS may set the RAB, for example, when an instantaneous RoT (RoT) measurement at the BS exceeds a RoT threshold. That is, namely, a RAB may be set when conventional RF overload is detected.

Alternatively, the serving BS may unset the RAB, for example, when an instantaneous RoT measurement at the BS does not exceed the RoT threshold.

Returning to FIG. 3, state machine 202_1 may remain in the normal state 302_1 while the average value RAB (RABavg) is below a BE block threshold BlockBEenterThr. That is, namely, the threshold used for transitioning the state machine 202_1 into a block state 302_2. RABavg may be obtained from the number of set RAB (e.g., RABs equal to ‘1’), for example, in a 16-slot frame. That is, namely, the RABavg may be the long-term averaged number of set RAB per frame. This long term average RABavg may be calculated by the RABavg calculator 206 shown in FIG. 2 based on each RAB. In example embodiments of the present invention, the RABavg may be more generally referred to as a congestion overload metric CO_metric. While RABavg has been described in this example embodiment as a congestion overload metric, other parameters may be used as the congestion overload metric.

Returning to FIG. 3, when the RABavg exceeds the BE block threshold BlockBEenterThr, the state machine 202_1 may transition into the block (or blocking) state 302_2, indicating that congestion overload for the BE service class has occurred. Accordingly, as discussed above with respect to FIG. 2, an overload flow block message may be sent to other system components within the serving BS, which are not shown for the sake of clarity. While in the block state 302_2, the system may reject (or block) new BE traffic flow requests to the system. While in the block state 302_2, the state machine 202_1 may compare the value of RABavg with a BE exit block threshold BlockBEExitThr. If the value of RABavg falls below the BE exit threshold BlockBEExitThr, the state machine 202_1 may return to the normal state 302_1 and blocking of new BE traffic flows may be discontinued.

In example embodiments of the present invention, the BE exit threshold BlockBEExitThr is lower than the BE block threshold BlockBEEnterThr to prevent repeatedly transitioning between, for example, the normal and block states.

Further, while in the block state 302_2, the state machine 202_1 may compare a value of the RABavg with another higher BE mute threshold MuteBEThr for transitioning the state machine 202_1 into the mute state 302_3. If the value of the RABavg exceeds the BE mute threshold MuteBEThr, the state machine 202_1 may transition into the mute (or muting) state 302_3. Accordingly, as discussed above with respect to FIG. 2, an overload flow mute message may be sent to other system components within the BS and/or the serving sector of the BS, which are not shown for the sake of clarity. In the mute state 302_3, the serving BS may determine which BE traffic flows are to be muted (e.g., all BE traffic flows or a subset thereof). That is, namely, the serving BS may instruct mobiles in the system to reduce transmission rates of existing BE traffic flows (e.g., gradually) to zero while maintaining an active call connection with the serving BS. While in the mute state 302_3, new BE traffic flows continue to be blocked; however, traffic flows belonging to other service classes (e.g., EF and/or AF traffic flows) may remain unaffected and, thus, may still be admitted to the system since these traffic flows are handled independently by other respective state machines.

As discussed above, in the mute state 302_3, in addition to blocking, at least a portion of existing BE traffic flows may be muted in an effort to relieve the overload condition. If the value of RABavg falls below the BE mute threshold BlockBEMuteThr, the state machine 202_1 may return to the block state 302_1. Accordingly, as discussed above with respect to FIG. 2, an overload flow block message may be sent to other system components within the serving BS, which are not shown for the sake of clarity, and the state machine 202_1 may operate in the manner as discussed above. When the value of RABavg falls below the BE mute threshold BlockBEMuteThr, the muted traffic flows may be unmuted, for example, gradually (e.g., using a round-robin format).

Methods for determining the proper fraction of traffic flows to be muted and/or the manner in which muted traffic flows are unmuted may be done in the same manner as used to unmute call connections (or users) on a per-call (or per-user) basis in conventional congestion overload control method. These conventional methods are well-known in the art and will not be described herein.

Returning to FIG. 3, the state machine 202_2 will now be described. The state machine 202_2 may remain in the normal state 304_1, while the value of the RABavg is below the EF block threshold BlockEFenterThr, which triggers the state machine 202_1 to transition into the block state 304_2.

As shown in FIG. 3, when the RABavg exceeds the EF block threshold BlockEFentefThr, the state machine 202_2 may transition to the block state 304_2. Accordingly, as discussed above with respect to FIG. 2, an overload flow block message may be sent to other system components within the serving BS, which are not shown for the sake of clarity. While in the block state 304_2, the state machine 202_2 may compare the value of RABavg with an EF exit threshold BlockEFExitThr to determine whether to return to the normal state 304_1. When the value of RABavg falls below the EF exit threshold BlockEFExitThr, the state machine 202_2 may return to the normal state 304_1 and blocking of new EF traffic flows may be discontinued.

In example embodiments of the present invention, the EF exit threshold BlockEFExitThr is lower than the EF block threshold BlockEFEnterThr to prevent repeatedly transitioning between, for example, the normal and block states.

While in the block state 304_2, the system may reject new EF traffic flow requests to the system, and may compare a value of the RABavg with another higher EF drop threshold DropEFThr for transitioning the state machine 202_2 into the drop state 304_3. When the value of the RABavg exceeds the EF drop threshold DropEFThr, the state machine 202_2 may enter the drop state 304_3. Accordingly, as discussed above with respect to FIG. 2, one or more overload flow drop messages may be sent to other system components within the serving BS, which are not shown for the sake of clarity. In the drop state 304_3, the serving BS may determine which existing EF traffic flows to drop (e.g., all EF traffic flows or a subset thereof). That is, namely, the serving BS may discontinue EF traffic flows with mobiles in the system. For example, the serving BS may drop EF traffic flow(s) with the highest guaranteed data rate and/or EF traffic flow(s) from mobiles experiencing the poorest system conditions. If the value of the RABavg falls below the EF drop threshold DropEFThr, the state machine 202_2 may return to the block state 304_2, and may operate in the same manner as discussed above.

Similar to that as discussed above with regard to muting and unmuting BE traffic flows, different methods for selecting the traffic flow(s) to drop may be similar to those used in a per-call (or per-user) basis in conventional congestion overload control method. These conventional methods are well-known in the art and will not be described herein. Furthermore, in example embodiments of the present invention, methods for muting and/or dropping traffic flows may be the same, or different, for different service classes.

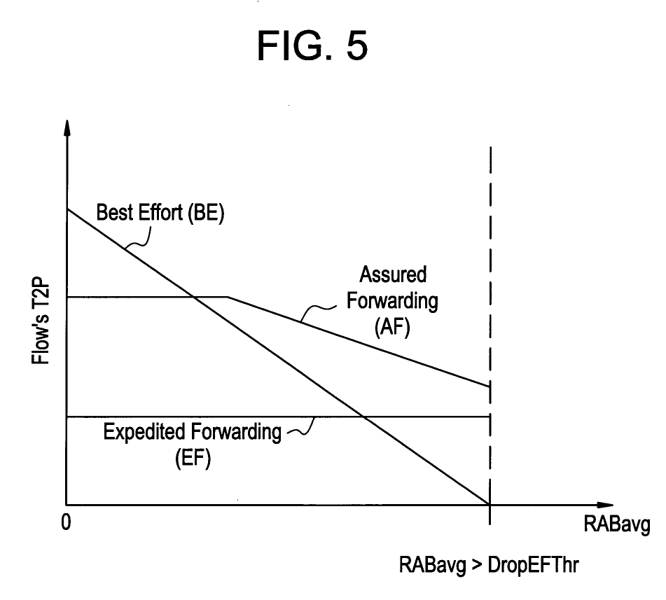

Furthermore, any or all of the thresholds discussed above with regard to the COC unit 202 may be determined, for example, by a human operator after observing system measurements provided by, for example, an RNC. In example embodiments of the present invention, thresholds used in, for example, the state machine 202_1 may be different from thresholds used in, for example, the state machine 202_2. The relationships that may be created by setting these thresholds will be discussed in greater detail below with respect to FIG. 5.

Returning to FIG. 2, the AC unit 204 may include flow admission control units 204_2-204_n, which may utilize real-time measurements or estimates and states of each corresponding congestion control state machine 202_2-202_n in determining whether to admit traffic flows on a per class or per flow basis. That is, namely, the flow admission control units 204_2-204_n may perform admission control independently for the second to nth service classes (e.g., EF, AF, etc) independently.

In example embodiments of the present invention, the real-time measurements or estimates may be made at the serving BS, for example, using first and second estimators 208 and 210, which, as discussed above, may be included in the AC unit 204. The first and second estimators 208 and 210 may be used to estimate a current system loading and a projected system loading, respectively.

For example, the first estimator 208 may calculate a long-term average RoT (e.g., aggregate RoT) within the system. The first estimator 208 may then determine a current system loading estimate using the aggregate RoT and traffic-to-pilot ratio behavior measurements or estimations for existing traffic flows within the system. For example, the first estimator 208 may derive a current system loading estimate from the RoT and measurements of pilot signal to noise ratios (Ecp/Nt) of active call connections within the system, evaluated as a sum of fractional loadings from the existing traffic flows and/or as a combination of these or any other suitable technique(s). The fractional loading may be modified to reflect expected traffic-to-pilot ratio for a respective traffic flow behavior under the higher loading conditions in the system.

For example, in the case of BE traffic flows, the fractional loading component due to the overhead channels may be included in the current system loading estimate. Whereas in the case of EF and AF traffic flows the fractional system loading may include a loading contribution of the traffic flow resulting from the guaranteed rate; that is, for example, the traffic-to-pilot ratio or RoT contribution caused by the guaranteed transmit rate. In addition, the estimated or measured loading contribution from the traffic flows connected to other systems (e.g., sectors/cells, etc) may also be included in the current loading estimate. The above discussed derivation and other techniques for determining a current system loading estimate using the aggregate RoT and traffic-to-pilot ratio behavior measurements or estimations are well-known in the art and, thus, will not be described in detail herein.

Returning to FIG. 2, the second estimator 210 may calculate an average received pilot signal to noise ratio (Ecp/Nt) of active call connections within the system based on received pilot signal to noise ratios (Ecp/Nt) of active call connections within the system. The second estimator 210 may then determine a projected loading increase due to the new traffic flow admission (e.g., belonging to any service class) based on the traffic-to-pilot ratio contribution by the new traffic flow.

In one example, for a new EF and/or AF traffic flows, the loading contribution at the guaranteed (or commnitted) rate may be used as an estimate of the projected loading increase. That is, namely, the loading contribution of the new EF and/or AF traffic flow may be used as an estimate of the resultant projected loading increase (or impact) if the new EF and/or AF traffic flow were admitted. In other examples, the additional loading as a result of the new overhead channels and/or increased interference from users connected to other systems (e.g., located in other cells or sectors) may be included in, and/or used as, the projected loading increase estimate. This projected system loading increase estimate may then be combined with the current system loading estimate to determine a projected system loading estimate. That is, for example, the second estimator 210 may add the projected system loading increase to the current system loading estimate provided from the first estimator 208, and the sum may be output as the projected system loading estimate.

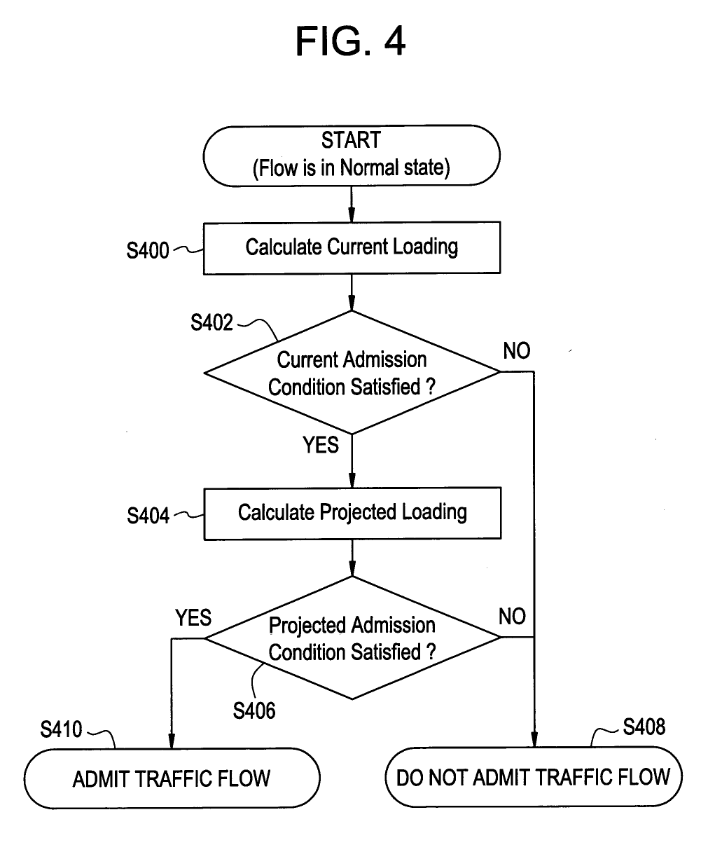

Returning again to FIG. 2, each admission control unit 204_2-204_n may have one or more admission thresholds, which represents the allowable system loading (e.g., a RoT tolerance). These admission thresholds may be determined, for example, by a human operator after observing system measurements provided by, for example, an RNC. The human operator may also utilize, for example, system behavior and status in order to make appropriate changes in operating parameters, as he/she sees fit. The admission thresholds may then be used to determine whether or not to admit a new traffic flow on a per-class or per-flow basis. That is, for example, the current system loading, the projected system loading and the admission thresholds may be used to determine if admission conditions are satisfied. The manner in which the above determination is made will be described in more detail with regard to FIG. 4.

FIG. 4 illustrates a method for traffic flow admission control on a per-class or per-flow basis, according to example embodiments of the present invention. Example embodiments of the present invention, as illustrated in FIG. 4, will be discussed below with regard to admission control unit 204_2 and state machine 202_2; however, it will be understood that the same method may be used by any or all of the flow admission control units 204_2-204_n and state machines 202_2-202_n. In example embodiments of the present invention, each of the state machines 202_2-202_n may determine overload conditions (e.g., states) of one of EF or AF traffic, and each may have a corresponding flow AC unit 204_2-204_n.

As discussed above with regard to FIGS. 2 and 3, if the BS detects a congestion overload state for a service class (e.g., one of the state machines 202_2-202_n enters a block, mute, or drop state), per-class (or per-flow) overload control may be performed in order to alleviate the overload condition. That is, for example, if an overload condition or congested state is detected (e.g., the state machines 202_1-202_n is in a block or a drop state), the state machine 202_1, for example, may mute at least a portion of the existing BE traffic flows to alleviate the overload state.

Referring to FIG. 4, if the state machine 202_2 is not in a normal state (e.g., the state machine 202_2 is in a block or drop state and is in a congested state), the state machine 202_2 may block new EF traffic flows or drop existing EF traffic flows, via overload flow block messages, flow drop messages, etc., until the state machine 202_2 returns to a normal state (e.g., the congestion state is alleviated). As a result, admission control is not performed by the respective admission control unit 204_2-204_n because the corresponding state machines 202_2-202_n has already prevented admission. As shown in FIG. 2, the state machines 202_2-202_n indicate their respective states to the corresponding admission control units 204_2-204_n so that this determination may be made.

However, when a state machine 202_2-202_n is in a normal state the process of FIG. 4 is run by the respective admission control unit 202_2-202_n. As shown, a current system loading estimate may be calculated by the first estimator 208 of FIG. 2, at step S400. At step S402, the admission control unit 204_i (for i=2 to i=n) may determine whether a current admission condition is satisfied. That is, for example, the EF admission control unit 204_2 may compare the current system loading estimate, provided by the first estimator 208, with a current EF admission threshold to determine if the current EF admission condition is satisfied. In example embodiments of the present invention, a current EF admission condition may be satisfied if the current system loading estimate passes the current EF admission threshold. That is, namely, the current EF admission condition may be satisfied if the current system loading estimate is less than the current EF admission threshold.

If the current admission condition is not satisfied, admission of the new EF traffic flow may be denied via an admission control message sent to other system components within the serving BS, which are not shown for the sake of clarity at step S408. Returning to step S402, if the current admission condition is satisfied, the method may proceed to step S404.

Returning to FIG. 4, at step S404, the second estimator 210 may determine a projected system loading estimate based on the new traffic flow for each service class. That is, for example, the second estimator 210 may determine the impact that the new EF traffic flow would have on existing calls, traffic flows in each service class, and/or mobiles. In the above example, the second estimator 210 may determine a projected system loading estimate as a result of the new EF traffic flow. However, in example embodiments of the present invention, the second estimator 210 may determine a projected system loading estimate for one or more traffic flows associated with one or more service classes. In example embodiments of the present invention, any newly admitted flow will be included into the existing loading for calculating the projected loading for next flow to be evaluated.

At step S406, the respective admission control units 204_2-204_n running the admission control process of FIG. 4 then determine if a respective projected admission condition is satisfied. For example, the EF admission control unit 204_2 may determine whether a projected EF admission condition is satisfied. That is, for example, the EF admission control unit 204_2 may compare the projected system loading estimate, provided by the second estimator 210, with a projected EF admission threshold to determine if the projected EF admission condition is satisfied. Similar to that as discussed above, a projected EF admission condition may be satisfied if the projected system loading estimate passes the projected EF admission threshold. That is, namely, the projected EF admission condition may be satisfied if the projected system loading estimate is less than the projected EF admission threshold.

If the projected EF admission condition is not satisfied, admission of the new EF traffic flow may be denied via an admission control message sent to other system components within the serving BS, which are not shown for the sake of clarity, at step S408. Returning to step S406, if the projected EF admission condition is satisfied, the EF traffic flow may be admitted at step S410 via an admission control message, and the mobile may begin transmitting the EF traffic flow to the serving BS in the uplink.

In example embodiments of the present invention, the admission condition thresholds (e.g., current and projected) may be different for each respective service class (e.g., EF, AF, etc.). Similarly, the congestion thresholds (e.g., BlockBEEnterThr, DropEFThr, etc.) may be different for each respective service class (e.g., BE, EF, AF, etc.). That is, for example, each of the congestion thresholds for lower service classes (e.g., BE) may be less than the congestion thresholds associated with higher service classes (e.g., EF) so that higher service class traffic may remain unaffected while lower service class traffic flows may be blocked, muted, etc.

In one example, congestion thresholds for BE service class (e.g., BlockBEEnterThr and MuteBEThr) may be less than the congestion thresholds for the EF service class (e.g., BlockEFEnterThr and DropEFThr). In this case, new BE traffic flows may be blocked, and existing BE traffic flows may be muted before new EF traffic flows are blocked or existing EF traffic flows are dropped. This may result in continued higher service class traffic flow transmission regardless of whether lower service classes are overloaded (e.g., state machines associated with lower service classes are in an overload state). Namely, system resources for BE traffic flows are sacrificed in favor of the higher class EF traffic flows.

FIG. 5 illustrates an expected behavior of a traffic-to-pilot ratio interference (or transmit rates) for existing BE, EF, and AF traffic flows while system loading increases based on an example set of admission condition and congestion thresholds. As shown in FIG. 5, prior to affecting existing AF traffic flows, BE traffic flows may be muted (e.g., transmission rate at which the BE flows are transmitting is reduced to zero) in an attempt to allow the AF and EF traffic flows to remain unaffected by the system loading increase. This muting of the BE flows results in the reduction of traffic-to-pilot ratio interference resulting from the BE traffic flows. If the muting of the BE traffic flows is determined to be insufficient based on the set thresholds, the AF traffic flows may behave similarly to BE traffic flows, and may respond to the increased system loading by downgrading (e.g., to a lower rate, for example, a minimum rate). However, unlike the BE traffic flows, which may reduce their transmission rates to zero, the AF traffic flows may maintain a minimum traffic-to-pilot ratio (or transmit rate) as the system loading increases.

In contrast to the BE and AF traffic flows, the traffic-to-pilot ratio (transmit rates) of EF traffic flows may not be affected by the system loading increase, until, for example, the EF traffic flows are dropped. That is, for example, if the muting of the BE and AF traffic flows is insufficient to allow the EF traffic flows to remain unaffected, the EF traffic flows may be dropped, for example, if the RABavg exceeds the EF drop threshold EFDropThr.

In example embodiments of the present invention, per-class admission decisions may be based on, for example, the state of the class state machine, the quality of service requirement of the new traffic flow, a current (e.g., existing) system loading estimate, projected system loading estimates and/or the impact the projected system loading estimate will have on existing users (e.g., existing call connections and/or traffic flows).

For EF traffic flows, muting may result in unacceptable degradation in transmission quality and, as a result, EF traffic flows may be dropped instead of muted. Example embodiments of the present invention provide different treatment per-class or per-flow by using independent state machines, which indicate system resource usage availability. Admission and overload control may then be defined in each admission control unit and state machine, respectively, for each service class independent of the other state machines or service classes. That is, for example, there may be no behavior correlation between the states (e.g., normal, block, and drop/mute) of different state machines or service classes, and the system may admit traffic flows with higher quality of service requirements, for example, while traffic flows with lower quality of service requirements are in an overload state (e.g., may be blocked).

Example embodiments of the present invention provide quality of service requirements on a per flow basis. That is, for example, each service class may be provided quality of service requirements independent of the other service classes.

Example embodiments of the present invention may provide more effective quality of service control in resource management and/or may ensure more efficient use of system resources.

The invention being thus described, it will be obvious that the same may be varied in many ways. Such variations are not to be regarded as a departure from the invention, and all such modifications are intended to be included within the scope of the invention.

We claim:

1. A method comprising:
determining whether to admit at least one traffic flow belonging to one of a plurality of service classes based on at least one admission condition associated with the service class to which the traffic flow belongs and an overload state associated with the service class to which the traffic flow belongs.

2. The method of claim 1, wherein the traffic flow is admitted if the overload state indicates that the service class to which the traffic flow belongs is not overloaded and the admission condition is satisfied.

3. The method of claim 2, wherein, in the determining step, a first admission condition is satisfied if a current system loading estimate passes a current admission threshold associated with the service class to which the traffic flow belongs.

4. The method of claim 3, wherein, in the determining step, a second admission condition is satisfied if a projected system loading estimate associated with the service class to which the traffic flow belongs passes a projected admission threshold associated with the service class to which the traffic flow belongs.

5. The method of claim 1, wherein the admission condition is satisfied if a projected system loading estimate associated with the service class to which the traffic flow belongs passes a projected admission threshold associated with the service class to which the traffic flow belongs.

6. The method of claim 4, further comprising:
calculating the current system loading estimate and the projected system loading estimate associated with the service class to which the traffic flow belongs.

7. The method of claim 6, wherein the current system loading estimate and the current admission threshold associated with the service class to which the traffic flow belongs are calculated based on an average rise over thermal and fractional average energy to noise ratio of the existing traffic.

8. The method of claim 6, wherein the projected system loading estimate and the projected admission threshold associated with the service class to which the traffic flow belongs are determined based on the existing loading and an energy to noise ratio of the traffic flow.

9. The method of claim 1, further comprising:
performing overload control for the service class if the overload state indicates an overload.

10. The method of claim 9, wherein overload state indicates an overload if a congestion overload metric is greater than a first threshold associated with the service class.

11. The method of claim 10, wherein the performing step further comprises:
blocking new traffic flows of the service class to which the traffic flow belongs if the congestion overload metric is greater than the first threshold.

12. The method of claim 11, wherein the performing step further comprises:
muting or downgrading at least a portion of existing traffic flows belonging to the service class to which the traffic flow belongs if the congestion overload metric is greater than a second threshold associated with the service class to which the traffic flow belongs, the second threshold being greater than the first threshold.

13. The method of claim 11, wherein the performing step further comprises:
dropping at least a portion of existing traffic flows belonging to the service class to which the traffic flow belongs if the congestion overload metric is greater than a second threshold associated with the service class to which the traffic flow belongs, the second threshold being greater than the first threshold.

14. The method of claim 1, wherein the service class to which the traffic flow belongs is one of a best effort, an assured forwarding, and an expedited forwarding service class.

15. A method comprising:
independently determining whether to admit each traffic flow among a plurality of traffic flows belonging to different service classes based on at least one admission condition for a service class to which each traffic flow belongs and an overload state for a service class to which each traffic flow belongs.

16. The method of claim 15, wherein the determining step basis admission on at least one of a current admission condition and a projected admission condition.

17. A method comprising:
determining whether a traffic flow service class from a plurality of traffic flow service classes is in an overload state based on a congestion overload metric and a first threshold associated with the traffic flow service class.

18. The method of claim 17, further comprising:
performing overload control if the determining step determines that the traffic flow service class is in overload state; wherein
the determining step determines that the traffic flow service class is in an overload state if the congestion overload metric is greater than the first threshold associated with the traffic flow service class.

19. The method of claim 18, wherein the performing step further comprises:
blocking at least one traffic flow of the service class if the congestion overload metric is greater than the first threshold associated with the traffic flow service class.

20. The method of claim 19, wherein the performing step further comprises:
muting or downgrading at least a portion of existing traffic flows belonging to the traffic flow service class if the congestion overload metric is greater than a second threshold associated with the traffic flow service class, the second threshold being greater than the first threshold.

21. The method of claim 19, wherein the performing step further comprises:
dropping at least a portion of existing traffic flows belonging to the traffic flow service class if the congestion overload metric is greater than a second threshold associated with the service class, the second threshold being greater than the first threshold.
